(19) United States
(12) Patent Application Publication
(10) Pub. No.: US 2010/0046079 A1
(43) Pub. Date: Feb. 25, 2010

(54) Polymer pattern and metal film pattern, metal pattern, plastic mold using thereof, and method of the forming the same

(76) Inventors: Jun-Bo Yoon, Daejeon (KR); Sung-il Chang, Daejeon (KR); Dae-Hyun Kim, Daejeon (KR); Hyung Suk Lee, Daejeon (KR); Joon-Yong Choi, Daejeon (KR); Weon-Wi Jang, Daejeon (KR); Kyungho Lee, Daejeon (KR)

Correspondence Address: FOLEY AND LARDNER LLP;SUITE 500, 3000 K STREET NW, WASHINGTON, DC, 20007, US

(21) Appl. No.: 10/584,409

(22) PCT Filed: Feb. 4, 2005
(86) PCT No.: PCT/KR05/00346

§ 371 Date: Aug. 5, 2009

(30) Foreign Application Priority Data
Feb. 12, 2004 (KR) 10-2004-0009291
Feb. 3, 2005 (KR) 10-2005-0009815

(51) Int. Cl. G02B 27/12; G03F 7/20; B32B 3/00; B29D 11/00; H01H 57/00; H05K 1/00

(52) U.S. Cl. 359/619; 430/322; 430/324; 430/325; 428/156; 425/470; 200/181; 174/250

(57) ABSTRACT

The present invention relates to polymer patterns of various shapes formed using modifications of means and methods used in the prior lithography process, and the metal film patterns, metal patterns and plastic molds using the polymer patterns, as well as methods of forming these patterns and molds. The method of forming the polymer patterns comprises the steps of: (a) depositing a photosensitive polymer on the substrate to form a polymer film; (b) placing a photomask on the polymer film; and (c) irradiating the polymer film with a light moving in random direction through the photomask, so as to form at least one pattern which is concave from the surface of the polymer film in a direction perpendicular to the substrate and extends in a direction parallel to the substrate. The inventive polymer patterns have at least one pattern which is concave from the surface of the polymer film in a direction perpendicular to the substrate and extends in a direction parallel to the substrate. The vertical cross-section of the concave patterns has at least one curved surface.

### TECHNICAL FIELD

The present invention relates to polymer patterns, and the metal film patterns, metal patterns and plastic molds using the polymer patterns, as well as methods of forming these patterns and molds. More particularly, the present invention relates to polymer patterns having a rounded shape which are formed using an incident light with random direction in a lithography process using a light source with a given wavelength, and to the metal film patterns, metal patterns and plastic molds formed using the same, as well as methods of forming these patterns and molds.

### BACKGROUND ART

Generally, in order to form metal interconnections in semiconductor integrated circuits and the like, polymer patterns are first formed by a photolithography process including photoresist deposition, light exposure and development steps.

FIG. 1 is a process flow diagram showing a method of forming positive photosensitive polymer patterns by the prior lithography process, and FIG. 2 is a cross-sectional view of metal patterns fabricated using the prior polymer patterns.

As shown in FIG. 1, polymer photoresist is first deposition on a substrate to form a photoresist film, and a photomask is placed on the photoresist film, and light exposure is performed by selectively irradiating light on the substrate having the photoresist film formed thereon (S10-S13). Then, the exposed photoresist film is subjected to a development process so as to remove portions of the photoresist film reacted with light, thus forming polymer patterns (S14).

In the cross-section of the prior polymer patterns thus formed, most of the polymer patterns have a rectangular vertical structure as shown in FIG. 2 because, in the exposure process of irradiating light on the substrate, a light perpendicular to the substrate is irradiated (S. Wolf and R. N. Tauber, “Silicon Processing for the VLSI Era, Volume 1—Process Technology”, Lattice Press, pp. 408, 1986).

Thus, metal interconnections formed on highly integrated circuits using the polymer patterns having a rectangular cross-sectional shape will also be formed of metal patterns having a rectangular cross-sectional shape (R. C. Jaeger, “Introduction to Microelectronic Fabrication”, Prentice Hall, pp. 167, 2002).

However, only with the prior polymer patterns or metal patterns having a rectangular shape, various demands for three-dimensional structures cannot be satisfied.

Such demands are listed as follows.

In the case of cantilever beams having a rectangular cross-section, during a process of removing a sacrificial layer between the substrate and the beams in the fabrication of devices, a stiction phenomenon where a substrate and the beams are stuck to each other occurs. This is the main cause of remarkably reducing the yield and uniformity of products in the fabrication of cantilever beams.

In order to prevent this stiction problem, various attempts are made which include critical point drying (G. T. Mulhern, et. al., “Supercritical Carbon Dioxide Drying of Microstructures”, Int. Conf. Solid-State Sensors and Actuators, Yokohama, Japan, pp. 296-299, 1993) and self-assembled monolayer (SAM) coating (U. Srinivasan, et. al., “Alkyltrichlorosilane-based Self-Assembled Monolayer Films for Stiction Reduction in Silicon Micromachines”, IEEE Journal of Microelectromechanical Systems, Vol. 7, pp. 252-260, 1998). However, these approaches have many problems in terms of cost and process stability.

Also in the case of curved electrodes used in optical microshutters (M. Pizzi, et. al., “Electrostatically driven film light modulators for display applications”, Microsystem Technologies, Vol. 10, pp. 17-21, 2003) and microswitches (S. Duffy, et. al., “MEMS microswitches for Reconfigurable Microwave Circuitry”, IEEE Microwave and Wireless Components Letters, Vol. 11, pp. 106-108, 2001), these electrodes have been made to have a curved shape using the stress of the electrodes themselves. However, in this case, it is very difficult to uniformly control the stress of the electrodes themselves, and thus, there is a problem in terms of process reproducibility.

Meanwhile, in the case of metal interconnections formed on semiconductor integrated circuits and the like, metal interconnections formed on the prior polymer patterns having a rectangular cross-sectional shape as shown in FIG. 2 in various manners will also have a rectangular cross-sectional shape.

Generally, as the operating frequency of integrated circuits gradually increases, metal interconnections have more effects on the performance of the integrated circuits depending on their length, width, thickness and cross-sectional shape. Thus, if the integrated circuits are operated by the application of voltage at high operating frequency, the corners of the cross-section of the metal interconnections will have high resistance so that the quality factor (Q factor) at high frequency will be reduced.

Also, as the operating frequency increases, the parasitic capacitance between adjacent metal interconnections is gradually increased, thus causing deterioration in the performance of circuits.

Furthermore, for a plastic microlens array which is necessarily used either in biochips or optical interconnections, a method is most widely used which comprises forming cylindrical photoresist patterns and then thermally treating the patterns at high temperature to form three-dimensional lens patterns. However, in the case of forming the microlenses by this method, there are fatal problems in that the thermal and chemical stabilities of the lenses are insufficient and the process reproducibility is low (Z. D. Popovic, et. al., “Technique for the monolithic fabrication of microlens arrays”, Appl. Opt., Vol. 27, pp. 1281-1284, 1988).

In addition, when the prior technology of thermally treating photosensitive polymers is used, there will be a problem in that it is very difficult to make a microlens array having a very high density (about 100%).

Also in the case of planar microlens arrays which are widely used for the communication between optical fibers or the biochips, there is a problem in that light is collected at a focal line, not at a focal point, due to the two-dimensional cylindrical shape of the lenses, thus reducing the light-collection efficiency of the lenses. For this reason, planar microlens arrays having a three-dimensional shape are required (S. Camou, et. al., “PDMS 2D optical lens integrated with microfluidic channels: principle and characterization”, Lab on a chip, Vol. 3, pp. 40-45, 2003).

### BRIEF DESCRIPTION OF DRAWINGS

FIG. 1 is a process flow diagram showing a method of forming positive photosensitive polymer patterns using the prior lithography process;

FIG. 2 is a cross-sectional view of metal patterns formed using the prior polymer patterns;

FIG. 3a is a perspective view of first polymer patterns formed according to the inventive lithography process;

FIG. 3b is a cross-sectional view of the first polymer pattern formed according to the inventive lithography process;

FIG. 3c is a secondary electron microscopic photograph taken for a portion of the cross-section of the first polymer patterns;

FIG. 4a is a perspective view of second polymer patterns formed according to the inventive lithography process;

FIG. 4b is a cross-sectional view of second polymer patterns formed according to the inventive lithography process;

FIG. 5 is a process flow diagram showing methods of forming the first and second polymer patterns by the inventive lithography process;

FIG. 6 shows polymer patterns obtained according to the kinds of diffusers.

FIG. 7 is a secondary electron microscopic photograph taken for a portion of the cross-section of third polymer patterns having a very high density, which are formed according to the inventive lithography process;

FIG. 8 is a secondary electron microscopic photograph taken for a portion of the cross-section of fourth polymer patterns having an obtuse slope to a substrate, which are formed according to the inventive lithography process;

FIG. 9a shows the structure of first metal film patterns away from a substrate so as to be suspended in space, which are formed according to the present invention;

FIG. 9b shows the structure of first metal film patterns being in contact with a substrate, which are formed according to the present invention;

FIG. 9c shows the structure of second metal film patterns according to the present invention, the inside of which is filled with polymer and which is away from the substrate so as to be suspended in space;

FIG. 9d shows the structure of second metal film patterns according to the present invention, the inside of which is filled with polymer and which is in contact with a substrate;

FIG. 9e shows the structure of third metal film patterns according to the present invention, the inside of which is empty and which is away from a substrate so as to be suspended in space;

FIG. 9f shows the structure of third metal film patterns according to the present invention, the inside of which is empty and which is in contact with a substrate;

FIG. 10 is a process flow diagram showing a method of forming the first, second and third metal film patterns according to the present invention;

FIGS. 11a and 11b show the open/closed states of metal film electrodes formed according to the metal film pattern-forming method of FIG. 10;

FIG. 11c shows cantilever beams with a rounded cross-section, which are formed according to the metal film pattern-forming method of FIG. 10;

FIG. 11d shows secondary electron microscopic photographs taken for the prior cantilever beams having a rectangular cross-section and for cantilever beams having a rounded cross-section according to the present invention;

FIG. 12a shows the structure of first metal patterns according to the present invention, which is away from a substrate so as to be suspended in space;

FIG. 12b shows the structure of first metal patterns according to the present invention, which is in contact with a substrate;

FIG. 12c shows the structure of second metal patterns according to the present invention, which do not expose a substrate;

FIG. 12d shows the structure of second metal patterns according to the present invention, which expose a substrate.

FIG. 13 is a process diagram showing methods of forming the first and second metal patterns according to the present invention;

FIG. 14 shows metal interconnections having a rounded cross-section, which are formed according to the method of FIG. 13;

FIGS. 15a to 15e show various structures of plastic molds according to the present invention;

FIG. 16 is a process flow diagram showing methods of forming the plastic molds according to the present invention;

FIG. 17 is a secondary electron microscopic photograph taken for a portion of a plastic microlens array formed according to the method shown in FIG. 16; and

FIG. 18 is a secondary electron microscopic photograph taken for a portion of a planar microlens array formed according to the method shown in FIG. 16.

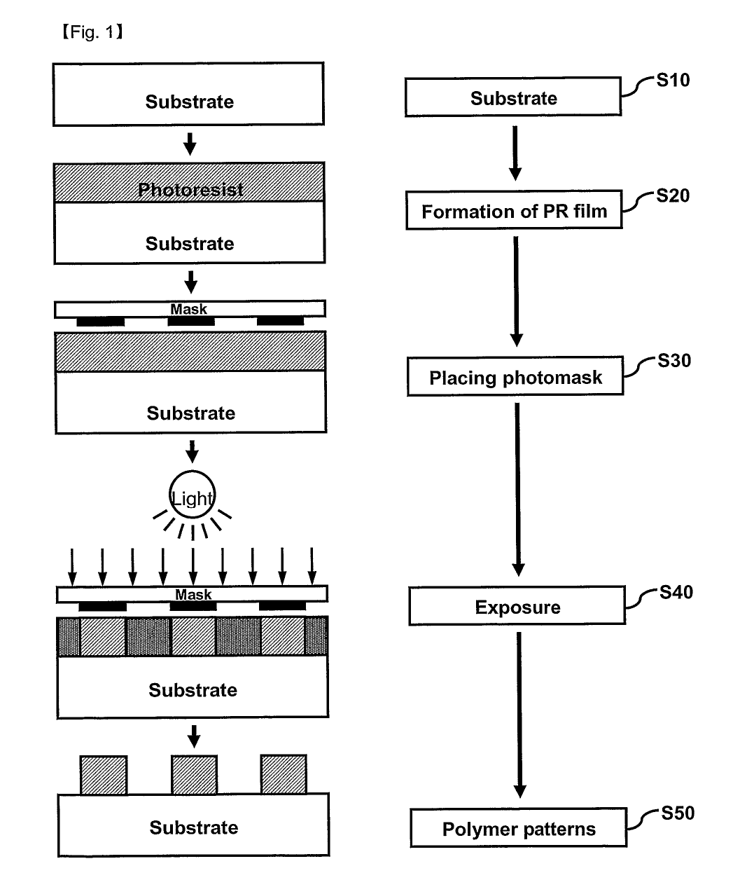

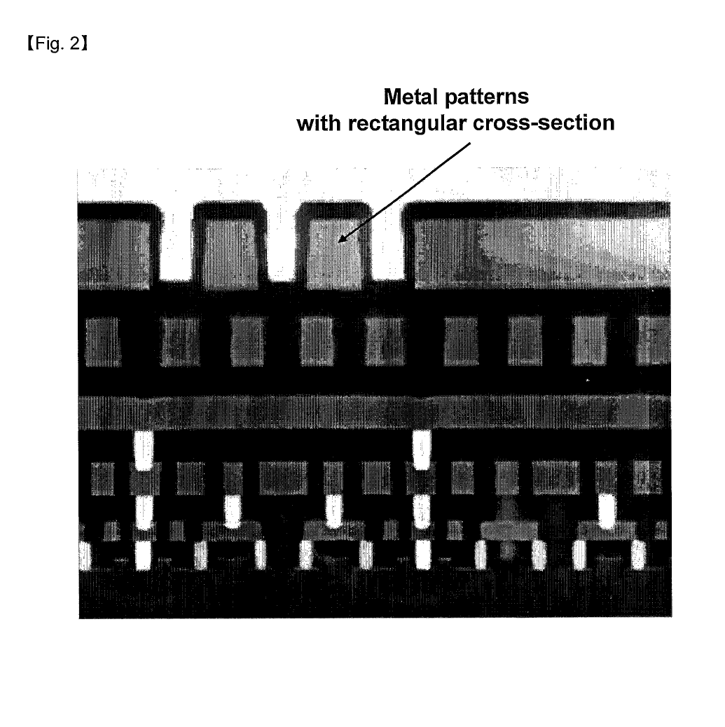

### DISCLOSURE OF INVENTION

### Technical Problem

The present invention has been made to solve the above-mentioned problems occurring in the prior art, and an object of the present invention is to provide the following: polymer patterns having any rounded shape and a method of forming the same using a modification of the prior lithography process; metal film patterns required either to form cantilever beams without the occurrence of stiction or to form curved electrodes in a very stable manner and a method of forming the metal film patterns using the polymer patterns; and metal patterns capable of improving the Q factor at high operating frequency and a method of forming the metal patterns using the polymer patterns.

Another object of the present invention is to provide plastic molds for forming patterns having a rounded cross-section, including microlens arrays with very high density, three-dimensional planar microlens arrays and microfluidic channels, and a method of forming the plastic molds using the polymer patterns.

### Technical Solution

To achieve the above objects, the present invention provides polymer patterns formed on a substrate in a given shape, the polymer patterns having at least one pattern which is concave from the surface of the polymer patterns and extends in a direction parallel to the substrate, wherein the vertical cross-section of the concave pattern has at least one curved surface.

The vertical cross-section of the concave pattern has a circular or oval shape, the top of which is cut in a straight line. And the polymer may be one of a positive photosensitive polymer and a negative photosensitive polymer.

Furthermore, the vertical cross-section of the concave pattern has a circular or oval shape, the top and bottom of which are cut in a straight line, and it can satisfy 90°>A>180° wherein A represents the angle between the lower surface of the polymer patterns and a straight line which connects a point where the upper surface of the polymer patterns meets the concave pattern to a point where the lower surface of the polymer patterns meets the concave pattern.

In another aspect, the present invention provides a method for forming polymer patterns on a substrate in a given shape, the method comprising the steps of: (a) depositing a photosensitive polymer on the substrate to form a polymer film; (b) placing a photomask on the polymer film; (c) irradiating the polymer film with a light moving in random directions through the photomask, so as to form at least one pattern which is concave from the surface of the polymer film in a direction perpendicular to the substrate and extends in a parallel direction to the substrate. The step (b) further comprises the sub-step (b-1) of placing a diffuser which serves to scatter the perpendicularly incident light source in random directions.

In yet another aspect, the present invention provides metal film patterns formed on a substrate in a given shape, the metal film patterns having at least one pattern which is concave in a direction perpendicular to the substrate and extends in a direction parallel to the substrate, wherein the vertical cross-section of the concave pattern has at least one curved surface.

The inside of the metal film patterns is filled with polymer or formed of empty space, and in some cases, the top of the metal film patterns is open.

A method for forming such metal film patterns comprises the steps of: (a) depositing a photosensitive polymer on the substrate to form a polymer film; (b) placing a photomask on the polymer film; (c) selectively irradiating the polymer film with the light moving in random direction through the photomask, so as to at least one pattern which is concave in direction perpendicular to the substrate and extends in a direction parallel to the substrate, in which the vertical cross-section of the concave pattern has at least one curved surface; and (d) depositing a metal film on the polymer patterns.

In this method, the step (b) further comprises the substep (b-1) of placing a diffuser on the photomask, in which the diffuser serves to scatter the perpendicularly incident light source in random directions. Also, the step (d) of depositing the metal film is performed by thin film deposition methods, including sputtering, or thick film-forming methods, including plating. Furthermore, this method may further comprise, after the step (d), the step of removing the polymer by means of a remover.

In yet another aspect, the present invention provides metal film electrodes having a curved metal electrode formed by said metal film pattern-forming method, in which the curved metal electrode is in an “on” or “off” state (closed/open states) depending on voltage difference applied across the two electrodes.

In still another aspect, the present invention provides cantilever beams formed by said metal film pattern-forming method, the cantilever beams having a rounded cross-section.

In yet another aspect, the present invention provides metal patterns formed on a substrate in a given shape, the metal patterns having at least one pattern which is concave in a direction perpendicular to the substrate and extends in a direction parallel to the substrate, in which the vertical cross-section of the concave pattern has at least one curved surface.

And, a method of forming the metal patterns according to the present invention comprises the steps of: (a) depositing a photosensitive polymer on the substrate to form a polymer film; (b) placing a photomask on the polymer film; (c) irradiating the polymer film with a light moving in random directions through the photomask, so as to form at least one pattern which is concave in a direction perpendicular to the substrate and extends in a direction parallel to the substrate, in which the vertical cross-section of the concave pattern has at least one curved surface; (d) depositing a metal material on the polymer pattern; and (e) removing the polymer by a remover.

In this method, the step (b) further comprises the substep of placing a diffuser on the photomask in which the diffuser serves to scatter the perpendicularly incident light source in random directions.

In yet another aspect, the present invention provides metal interconnections formed by said metal pattern-forming method, in which the metal interconnections have a rounded cross-section.

In another further aspect, the present invention provides a plastic mold having a given shape, in which all or part of the cross-section of at least one protrusion formed on the surface of the plastic mold has a rounded surface. Meanwhile, the inside of the plastic mold is formed of empty spaces which serve as microfluidic channels.

A method of forming the plastic mold according to the present invention comprises the steps of: (a) depositing a photosensitive polymer on a substrate to form a polymer film; (b) placing a photomask on the polymer film; (c) irradiating the polymer film with a light moving in random directions through the photomask, so as to form polymer patterns, all or part of the vertical cross-section of which has a rounded surface; (d) depositing and solidifying a polymer having properties different from those of the photosensitive polymer on the photosensitive polymer; (e) separating the solidified polymer from the photosensitive polymer or substrate; and (f) removing the photosensitive polymer from the solidified polymer.

### Advantageous Effects

As described above, the present invention has the effect capable of forming three-dimensional polymer patterns having various shapes using modifications of the means and methods used in the prior lithography process.

Also, the use of the polymer patterns according to the present invention allows the formation of positive photosensitive polymer patterns having an obtuse slope to the substrate. This can eliminate a need for the use a negative photosensitive polymer which is generally used in a lift-off process and the like. Thus, the cost competitiveness and easiness of processes can be improved.

Moreover, the metal film patterns formed using the inventive polymer patterns is very stable, can be easily prepared in various shapes, and can be used to form curved electrodes having high reliability. Such curved electrodes can be widely used in optical microshutters, microswitches and the like, and thus, can be regarded as having a very great commercial effect.

Also, the cantilever beams having a rounded cross-section can be formed with the metal film patterns formed using the inventive polymer patterns. This can solve the problem of stiction to the substrate, which has been a great problem in forming the cantilever beam according to the prior art.

Furthermore, the metal patterns formed using the inventive polymer patterns can be interconnected on devices having integrated circuits so as to improve the operating properties of the integrated circuits at high frequency.

Also, the plastic mold formed using the inventive polymer patterns can be prepared in a simpler process and lower material cost than those of the prior microscale fluidic channels. Also, this plastic mold can be used to make a microlens array whose optical properties can be controlled in a very simple manner.

In addition, the plastic mold formed using the inventive polymer pattern can be used to make a three-dimensional planar microlens array having very excellent light collection efficiency.

### Best Mode for Carrying Out the Invention

Hereinafter, the polymer patterns according to the present invention, and the metal film patterns, metal patterns and plastic molds using the polymer patterns, as well as methods of forming these patterns and molds, will be described in detail with reference to the accompanying drawings.

### EMBODIMENT 1

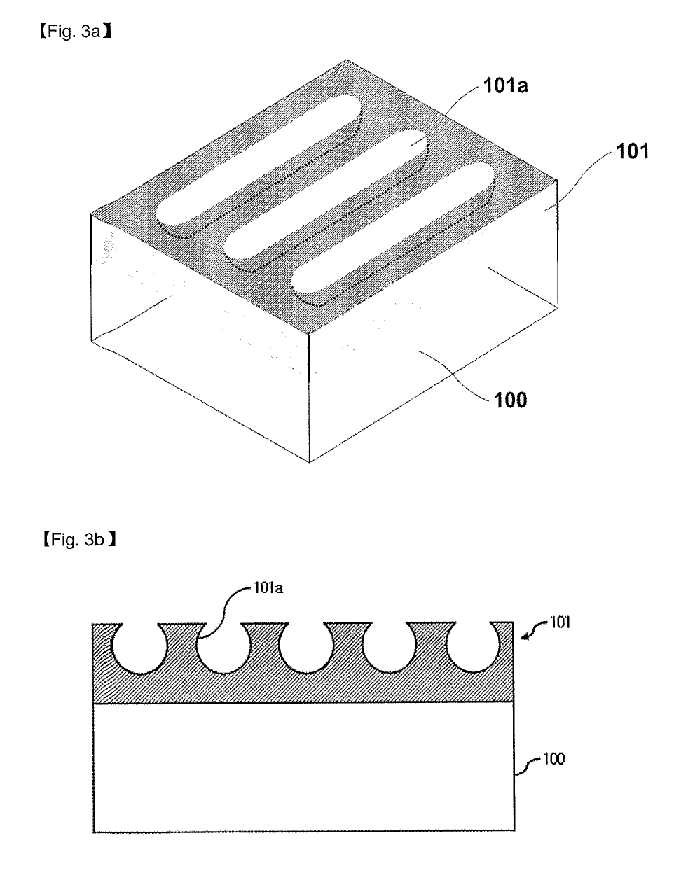

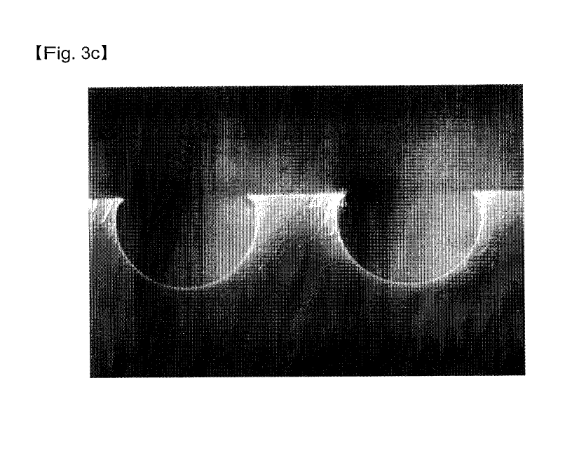

FIG. 3a is a perspective view of first polymer patterns formed according to the inventive lithography process, FIG. 3b is a cross-sectional view of the first polymer patterns formed according to the inventive lithography process, and FIG. 3c is a secondary electron microscopic photograph taken for a portion of the cross-section of the first polymer patterns.

Referring to FIGS. 3a to 3c, the first polymer patterns have the patterns 101a which are concave from the surface of the polymer film 101 deposited on the substrate 100 in a direction perpendicular to the substrate 100 and extend in a direction parallel to the substrate 100. The vertical cross-section of the concave patterns has at least one curved surface.

Namely, as shown in the drawings, the concave patterns 101a are so formed that they have a circular or oval shape, the top of which is cut in a straight line. These circular or oval patterns can vary in their shape or depth depending on the amount of UV applied during the lithography process.

The polymer used in this case is preferably a positive photosensitive polymer whose exposed region is removed during development.

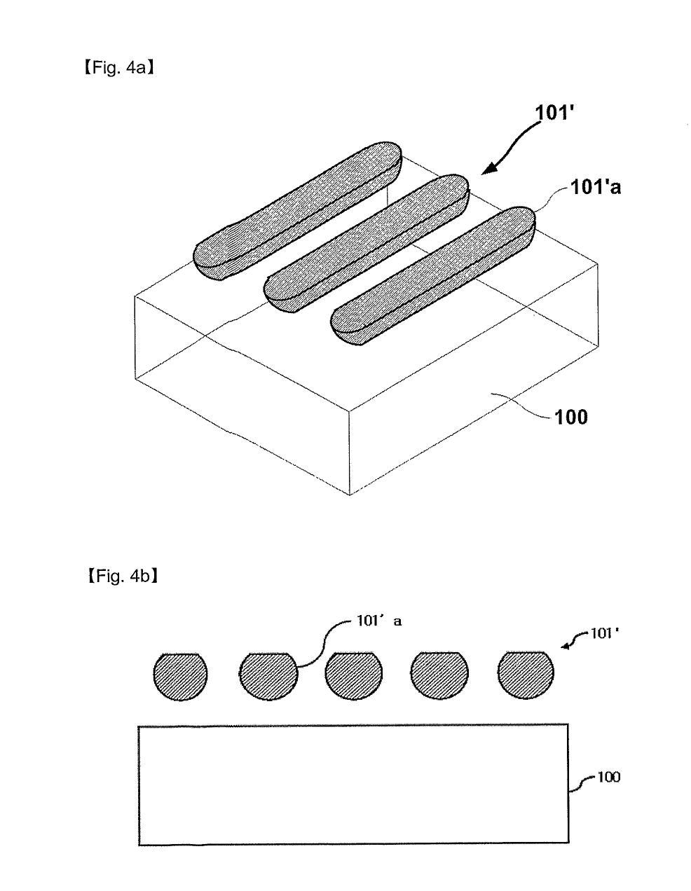

FIG. 4a is a perspective view of second polymer patterns formed according to the inventive lithography process, and FIG. 4b is a cross-sectional view of the second polymer patterns formed according to the inventive lithography process.

Referring to FIGS. 4a and 4b, the second polymer patterns have the patterns 101′a which are concave extends from the surface of the polymer film 101′ deposited on the substrate 100 in a direction perpendicular to the substrate 100 and extend in a direction parallel to the substrate 100. The vertical cross-section of the concave patterns has a circular or oval curved shape, the top of which is cut in a straight line.

Similarly to the first polymer patterns, these second polymer patterns can vary in their shape or depth depending on the amount of UV applied during the lithography process.

The polymer used in this case is preferably a negative photosensitive pattern whose exposed region remains undeveloped.

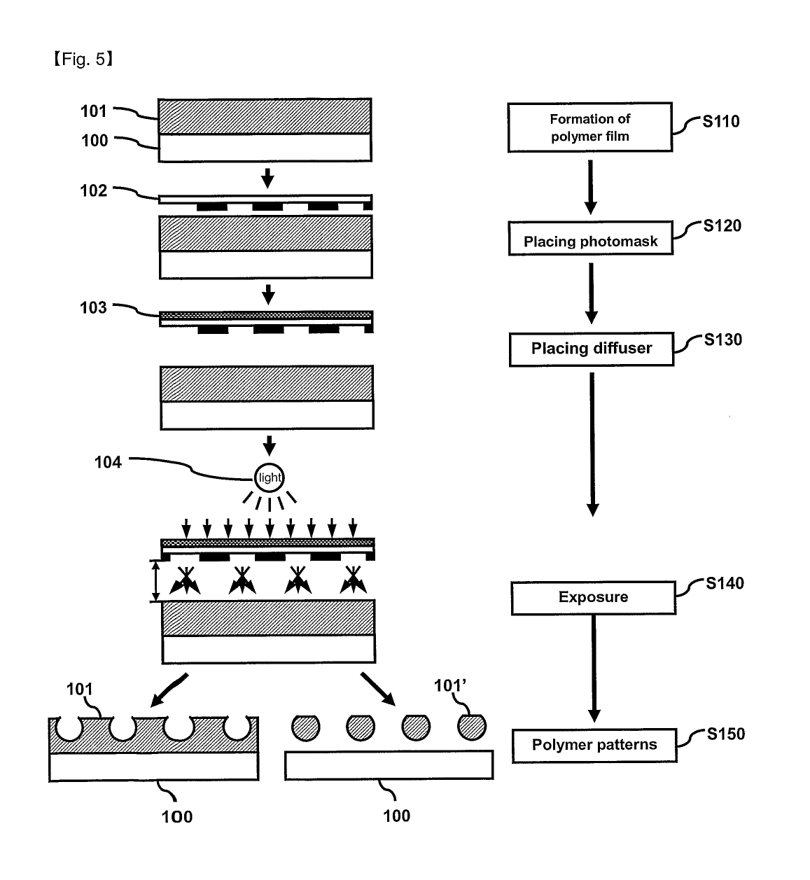

The first and second polymer patterns according to the present invention are formed by methods shown in FIG. 5 as described below.

FIG. 5 is a process flow, diagram showing the methods of forming the first and second polymer patterns by the inventive lithography process. As shown in FIG. 5, in the methods of forming the first and second polymer patterns according to the present invention, a photosensitive polymer is deposited on the substrate 100 to form the polymer film 101 (S110). The substrate 100 used is one of a semiconductor substrate, a glass substrate, a liquid crystal panel and the like.

Then, the photomask 102 having a given pattern formed thereon is placed on the polymer film 101, and the diffuser 103 having high light-scattering ability is placed on the photomask 102 (S120 and S130). Then, using the light source 104, the polymer film 101 is irradiated with a light of a given wavelength. At this time, the perpendicularly incident light emitted from the light source 104 is irradiated on the polymer film 101 in random directions after passing through the diffuser 103, thus forming the first and second polymer patterns 101 and 101′ having a curved surface, the top of which is cut in a straight line (S140 and S150).

In this case, the first and second patterns 101 and 101′ are different depending on the properties of the photosensitive polymers used. Namely, in the case of a positive photosensitive polymer whose exposed region is removed during development, an exposed region of the polymer film 101 is etched to form a concave pattern. In the case of a negative photosensitive polymer whose exposed region remains undeveloped, an exposed portion itself in the polymer film 101 form a pattern.

Meanwhile, the first and second patterns 101 and 101′ formed as described above can vary in their microshapes depending on various factors, including the movement direction of the light source 104 in the lithography process, kind of the diffuser, the amount of light irradiated on the polymer film 101, and proximity gap, a gap between the photomask 102 and the substrate 100 upon exposure. If the light incident on the polymer 101 is well diffused in random directions, a concave pattern in a direction perpendicular to the substrate will be formed in the cross-section of the polymer film 101. As shown in FIG. 6, this concave pattern will vary in its shape depending on the kind of a diffuser.

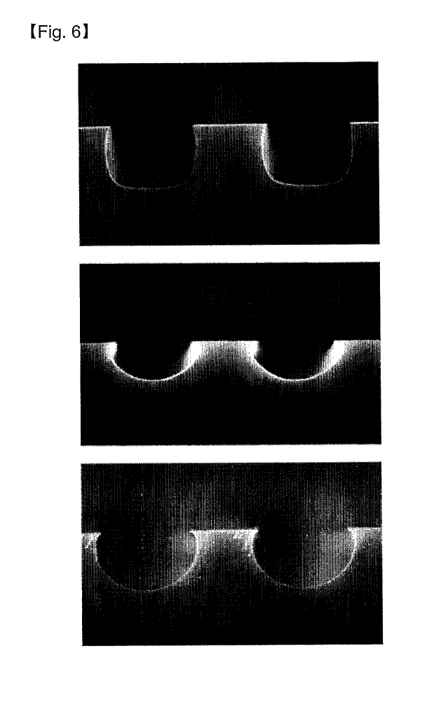

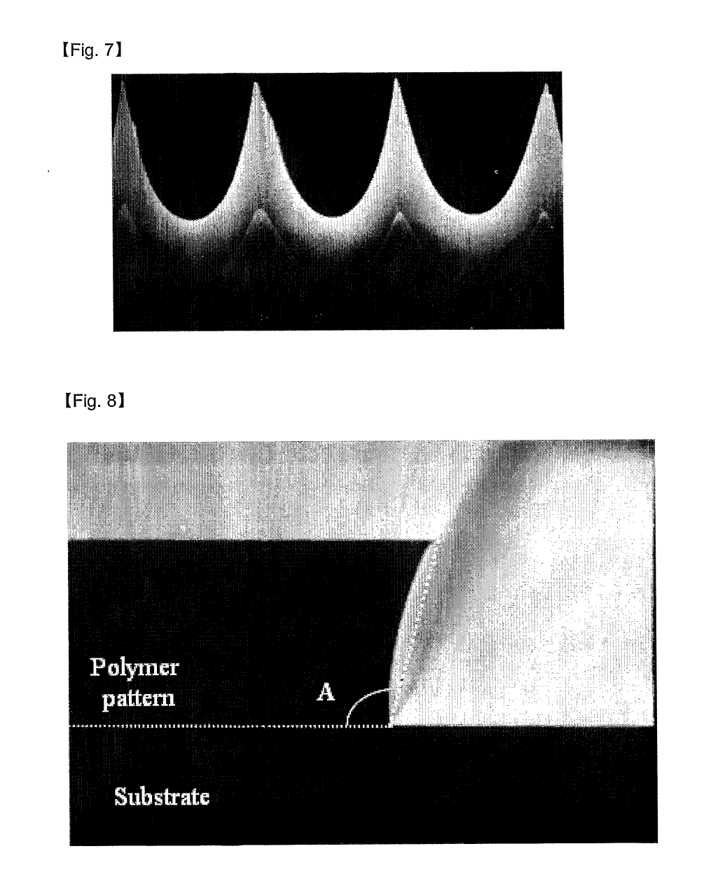

FIG. 6 shows polymer patterns obtained according to the kinds of diffusers in experiments of the present invention, FIG. 7 is a secondary electron microscopic photograph taken for a portion of the cross-section of third polymer patterns having a very high density, which are formed according to the inventive lithography process, and FIG. 8 is a secondary electron microscopic photograph taken for the partial cross-section of fourth polymer patterns having an obtuse slope to a substrate, which are formed according to the inventive lithography process.

Referring to FIG. 6, the photograph (a) of FIG. 6 shows polymer patterns having an almost rectangular cross-section, which are obtained by performing a lithography process using F43-725 diffuser (Edmund Optics).

The photograph (b) of FIG. 6 shows the cross-sectional structure of polymer patterns obtained by performing the lithography process using F45-656 diffuser (Edmund Optics). These polymer patterns have a concave shape formed downward toward the substrate, but have small curvature due to low light diffusion.

The photograph (c) of FIG. 6 shows the cross-sectional structure of polymer patterns obtained by performing the lithography process using F43-719 diffuser (Edmund Optics). The cross-sectional structure of such polymer patterns has a shape downward toward the substrate, and they are concave patterns with high curvature.

It can be seen from FIG. 6 that the shape of the polymer patterns varies depending on the kind of the diffuser used in the polymer pattern-forming method. Thus, it is understood that other polymer patterns obtained using other kinds of diffusers will be within the technical scope of the present invention.

Also, as the amount of light irradiated on the polymer film increases, the cross-sectional structure of the polymer film shows a more concave shape toward the substrate, and as the proximity gap increases, the depth of the concave pattern becomes low, instead the width widens.

Meanwhile, when the spacing between the open patterns on the mask is reduced to some extent in the lithography process, adjacent polymer patterns will be influenced after the lithography process so that, as shown in FIG. 7, polymer patterns having a rounded cross-section can be formed at high density. Such patterns with high density, which cannot be formed by the prior lithography technology, can be formed only by the present invention.

Also, the preparation of photosensitive polymer patterns having the obtuse slope A to the substrate as shown in FIG. 8 was an expensive and difficult process since such patterns could only be formed using a negative photosensitive polymer, which is expensive and hard to handle. However, this preparation can be easily achieved by using a positive photosensitive polymer according to the present invention in which the lithography process is performed using a sufficient amount of light irradiation.

In FIG. 8, the reference mark A is defined as the angle between the lower surface of the polymer pattern and a straight line which connects a point where the upper surface of the polymer pattern meets the concave pattern to a point where the lower surface of the polymer pattern meets the concave pattern.

The inventive positive photosensitive polymer pattern thus formed can enhance the cost competitiveness of a lift-off process and the like and can make these processes easy.

### EMBODIMENT 2

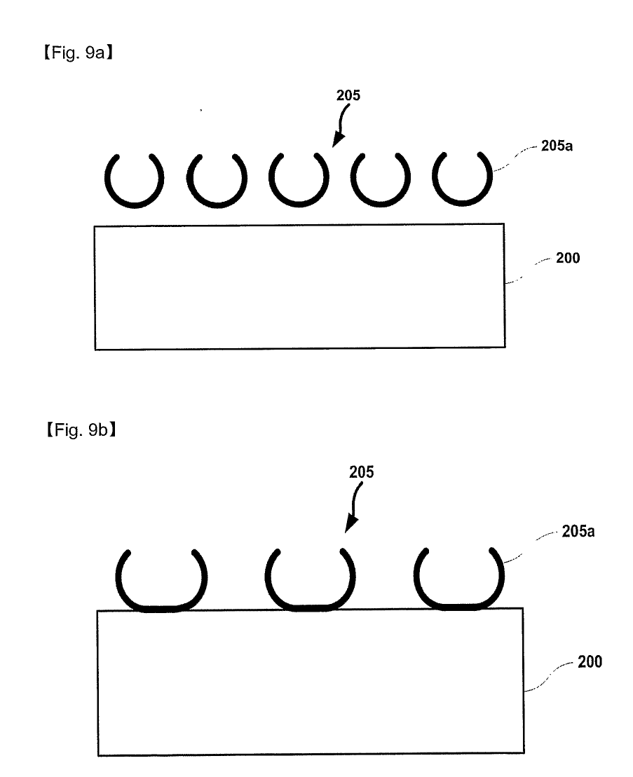

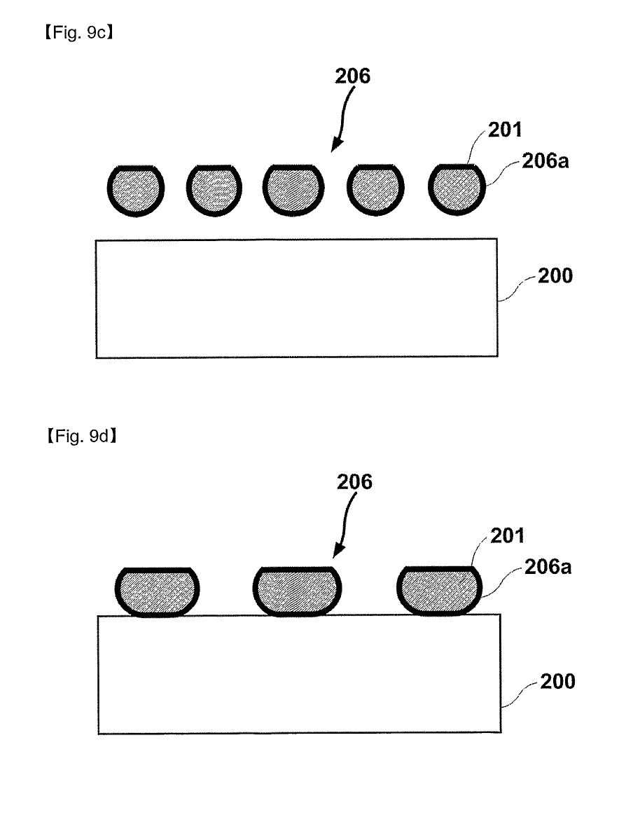

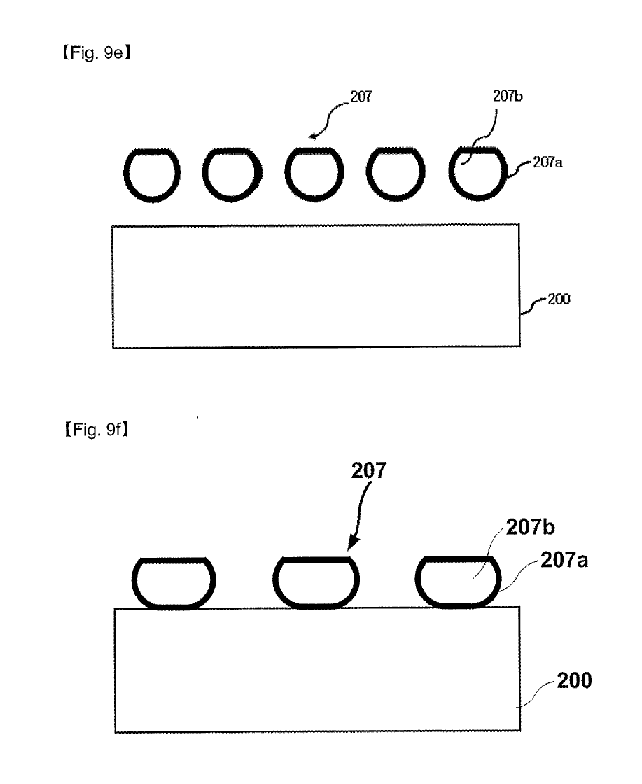

FIGS. 9a and 9b show the structure of first metal film patterns of a given shape according to the present invention, FIGS. 9c and 9d show the structure of second metal film patterns of a given shape according to the present invention, and FIGS. 9e and 9f show the structure of third metal film patterns of a given shape according to the present invention.

For reference, like reference numerals denote like elements throughout the drawings.

Referring to FIGS. 9a and 9b, the first metal film patterns 205 have pattern 205a which are concave in a direction perpendicular to the substrate 200 and extend in a direction parallel to the substrate 200. The vertical cross-section of the concave pattern 205a is open at its top and has at least one curved surface.

Depending on the formation position of the patterns, the first metal film patterns 205 are so formed that they are away from the substrate 200 so as to be suspended in space or are in contact with the substrate 200.

As shown in 9c and 9d, the second metal film patterns 206 have patterns 206a which are concave in a direction perpendicular to the substrate 200 and extend in a direction parallel to the substrate 200. The inside of the concave patterns 206a is filled with the polymer 201.

Depending on the formation position of the patterns, the second metal film patterns 206 are so formed that they are away from the substrate 200 so as to be suspended in space or are in contact with the substrate 200.

As shown in FIGS. 9e and 9f, the third metal film patterns 207 have patterns 207a which are concave in a direction perpendicular to the substrate 200 and extend in a direction parallel to the substrate 200. The inside of the concave patterns 207a is formed of the empty space 207b. Thus, unlike the first metal film patterns 205 shown in FIGS. 9a and 9b, the concave patterns 207a have a closed cross-section whose top is not open.

Depending on the formation position of the patterns, the third metal film patterns 207 are so formed that they are some distance from the substrate 200 or in contact with the substrate 200.

As described above, the first, second and third metal film patterns 205, 206 and 207 are structures resulting from the first and second polymer patterns of Embodiment 1. These patterns have a geometrical shape of a rounded cross-section extending in a direction perpendicular to the substrate, unlike metal patterns having a rectangular cross-section obtained by the prior lithography process.

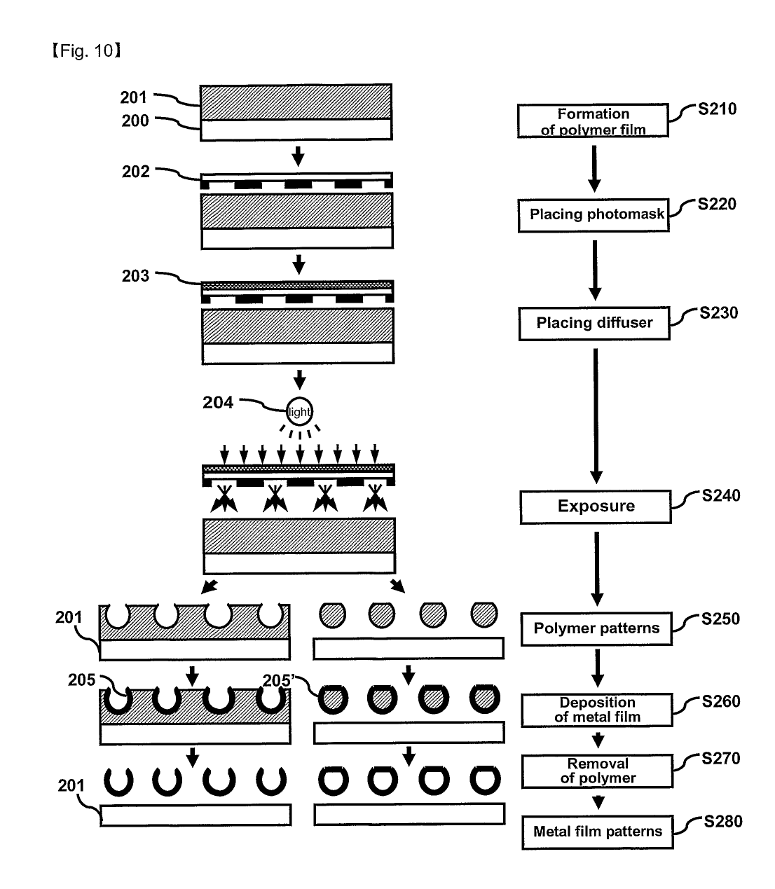

Methods of forming the first, second and third metal film patterns 205, 206 and 207 having such structures are shown in FIG. 10.

FIG. 10 is a process flow diagram showing the methods of forming the first, second and third metal film patterns according to the present invention.

As shown in FIG. 10, the metal film pattern-forming methods of the present invention comprise performing the above-described polymer pattern-forming methods, and then, depositing a metal film on the polymer patterns having a given shape so as to form the metal film patterns.

Namely, a photosensitive polymer is deposited on the substrate 200 to form the polymer film 201. Then, the photomask having a given pattern formed thereon is placed on the polymer film 201, after which the diffuser 203 having high light-scattering ability is placed on the photomask 202 (S210-S230). Then, using the light source 204, the polymer film 201 is irradiated with light of a given wavelength. At this time, the perpendicularly incident light emitted from the light source 204 is irradiated on the polymer film 201 in random directions after passing through the diffuser 203 so as to form the first and second polymer patterns 201 and 201′ having a concave shape, the top of which is cut in a straight line (S240 and S250). In this case, the first and second patterns 201 and 201′ are different depending on the properties of the photosensitive polymers.

On the first and second polymer patterns 201 and 201′ thus formed, the metal film 205 is deposited to form concave patterns in a direction perpendicular to the substrate 200 and to form metal film patterns which are arranged in parallel (S260 and S280).

If necessary, after depositing the metal film, the step of removing the polymer patterns 201 and 201′ by means of a remover may also be performed (S270).

As in Embodiment 1, the light used in this case is scattered by the diffuser which serves to scatter the light source perpendicularly incident to the surface of the polymer film in random directions. For this reason, the first, second and third metal film patterns 205, 206 and 207 are different depending on the properties of the photosensitive polymers used.

Although the deposition of the metal film 205 on the polymer patterns may be performed by the prior method used in coating on a base substrate such as the substrate 200, it is preferably conducted by any of thin film deposition methods, including sputtering, and thick film-forming methods, including plating.

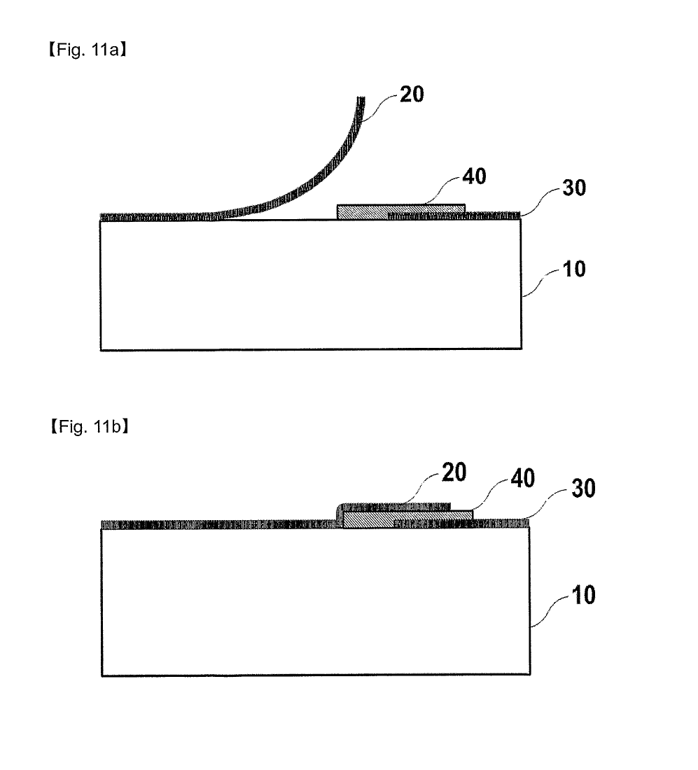

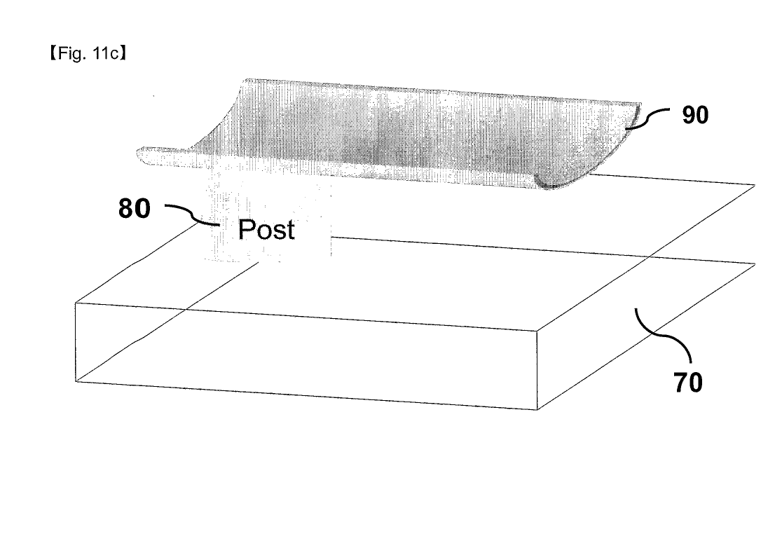

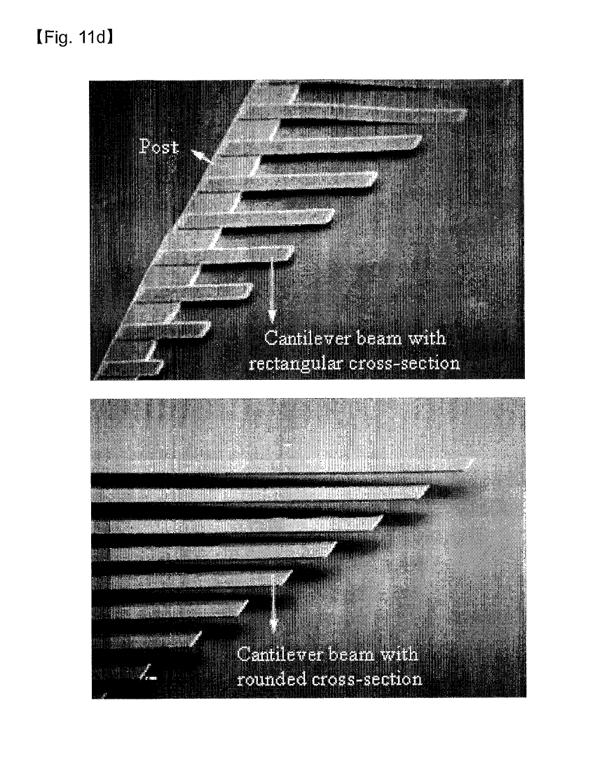

FIGS. 11a and 11b show the closed and open states of the metal film electrodes formed by the metal film pattern-forming method of FIG. 10.

As shown in FIGS. 11a and 11b, the metal film electrode 20 is a curved metal electrode which is curved in a direction opposite to the substrate 10 in such a way that its both ends are far away from the substrate 10. This curved metal electrode 20 and an electrode opposite thereto are operated according to the voltage applied across the two electrodes to perform on/off actions. Namely, when the voltage difference between the metal film electrode 20 and the opposite electrode occurs, the metal film electrode 20 then moves by electrostatic force. Thus, as shown in FIG. 11a, if the electrode 20 is placed far away from the underlying electrode 30, the electrodes 20 and 30 will be in an open state, and if the electrode 20 moves to and contacted with the underlying electrode 30 as shown in FIG. 11b, the electrodes 20 and 30 will be in a closed state.

Between the metal film electrode 20 and the underlying electrode 30, the contact prevention layer 40 is formed in order to prevent electrical short circuits caused by the direct contact there between.

This curved metal film electrode 20 is formed in a more stable manner as compared to the prior metal film-forming method where the metal film is curved due to its stress. Also, the curved degree of the metal film electrode can be easily controlled depending on the rounded degree of the polymer pattern, so that the process uniformity and stability and also the product reliability, can be improved.

FIG. 11c shows a cantilever beam having a rounded cross-section formed by the metal film pattern-forming method of FIG. 10. As shown in FIG. 11c, the cantilever beam 90 has a rounded cross-sectional shape unlike the prior cantilever beam. This can significantly reduce the stiction phenomenon where the substrate 70 and the cantilever beam are stuck to each other when the polymer used as the sacrificial layer is removed after forming the cantilever beam. The reference numeral 80 denotes a post to support the load of the cantilever beam 90.

FIG. 11d shows secondary electron microscopic photographs taken for the prior cantilever beams having a rectangular cross-section and the cantilever beams having a rounded cross-section according to the present invention. As shown in FIG. 11d, the prior cantilever beams having a rectangular cross-section is prone to undergo the phenomenon of stiction to the substrate despite their short length, and the cantilever beams having a rounded cross-section are away from the substrate so as to be suspended in space.

### EMBODIMENT 3

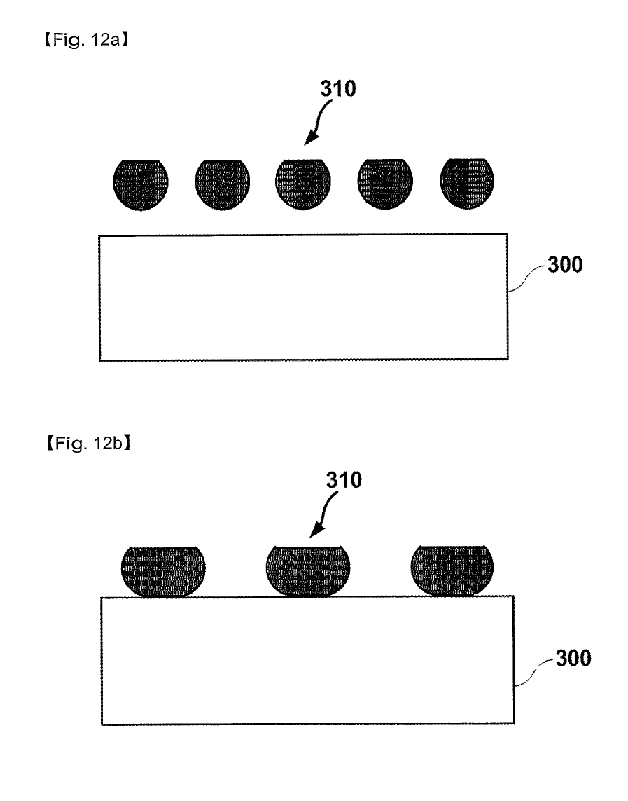

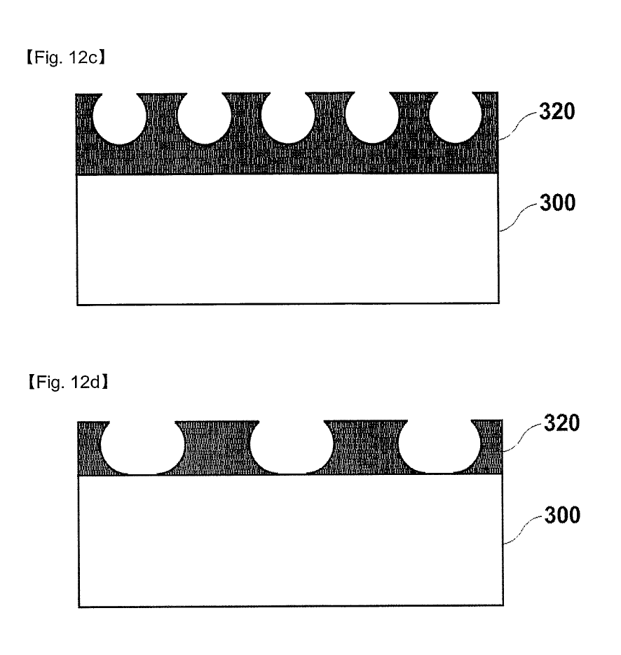

FIGS. 12a and 12b show the structure of first metal patterns having a given shape according to the present invention, and FIGS. 12c and 12d show the structure of second metal patterns having a given shape according to the present invention.

As shown in FIGS. 12a and 12b, the first metal patterns 310 have concave patterns formed on the substrate 300 in a direction perpendicular to the substrate 300 and extending in a direction parallel to the substrate 300. The vertical cross-section of the concave patterns has at least one curved surface.

Namely, the concave patterns shown in FIGS. 12a and 12b have a rod shape with a circular or oval cross-section, the top of which is cut in a straight line. These circular or oval patterns can vary in their shape or depth depending on the amount of UV irradiated during the lithography process.

Depending on the formation position of the metal patterns, the first metal patterns 310 are away from the substrate 300 so as to be suspended in space or are in contact with the substrate 300.

Referring to FIGS. 12c and 12d, the second patterns 320 according to the present invention have patterns which are concave from the surface of the metal film deposited on the substrate 300 and extend in a direction parallel to the substrate. The vertical cross-section of the concave patterns has a curved surface of a circular or oval shape, the top of which is cut in a straight line.

These curved patterns can vary in their shape or length depending on the amount of UV irradiated during the lithography process.

Depending on the formation position of the metal patterns, the second metal patterns 320 can be so formed that they are away from the substrate 300 so as to be suspended in space or are in contact with the substrate 300.

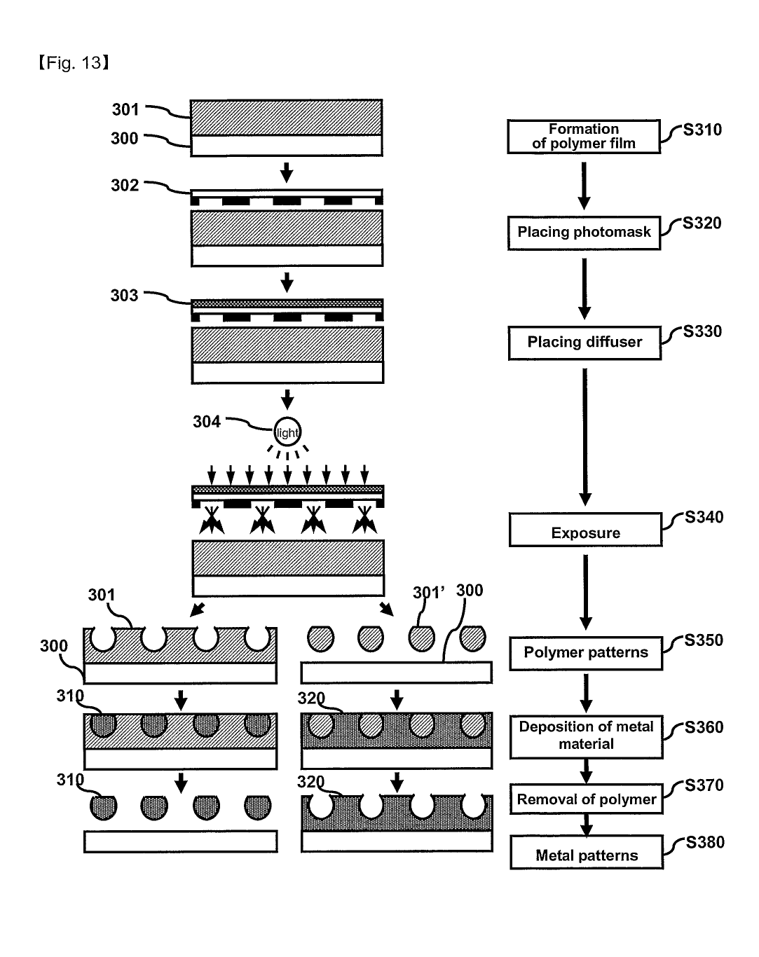

Methods for forming the first and second metal patterns of having the above-described structure according to the present invention are shown in FIG. 13.

FIG. 13 is a process flow diagram showing the methods of the first and second metal patterns according to the present invention.

As shown in FIG. 13, the metal pattern-forming methods of the present invention comprise performing the polymer pattern-forming methods described in Embodiment 1, and then, depositing a metal material to form metal patterns.

Namely, a photosensitive polymer is deposited on the substrate 300 to form the polymer film 301 on which the photomask 302 having a given pattern formed thereon is placed. On the photomask 302, the diffuser having high light scattering ability is placed (S310-330). Then, using the light source 304, the polymer film 301 is irradiated with light of a given wavelength. At this time, the perpendicularly incident light emitted from the light source 304 is irradiated on the polymer film 301 in random directions after passing through the diffuser 303 so as to form the first and second polymer patterns 301 and 301′ having a curved surface of an circular or oval shape, the top of which is cut in a straight line (S340 and S350). In this case, the first and second polymer patterns 301 and 301′ are different depending on the properties of the photosensitive polymers used.

On the first and second polymer patterns 301 and 301′ thus formed, metal materials 310 and 320 are deposited to the same height as the first and second polymer patterns 301 and 301′. Then, the polymer patterns 301 and 301′ are removed by means of a remover, thus forming concave metal patterns in a direction perpendicular to the substrate 300 (S360-S380). The first and second metal patterns are also different depending on the properties of the photosensitive polymers used.

The deposition of the metal materials 310 and 320 is performed by any of thin film deposition methods, including sputtering, and thick film-forming methods, including plating.

FIG. 14 shows metal interconnections having a rounded cross-section, formed by the methods shown in FIG. 13. When such metal interconnections having a rounded cross-section are formed on semiconductor integrated circuits and the like by an insulator, an increase in resistance and an increase in parasitic capacitance between adjacent metal interconnections can be prevented even at high frequency.

### EMBODIMENT 4

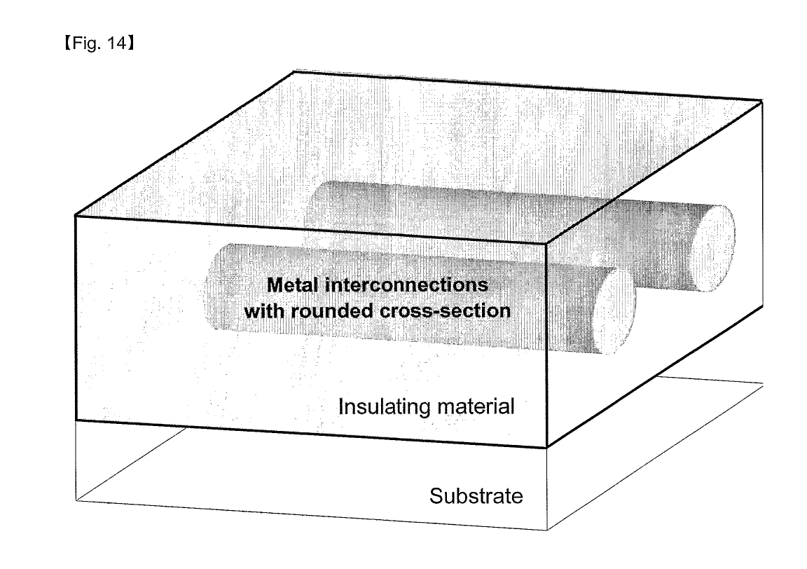

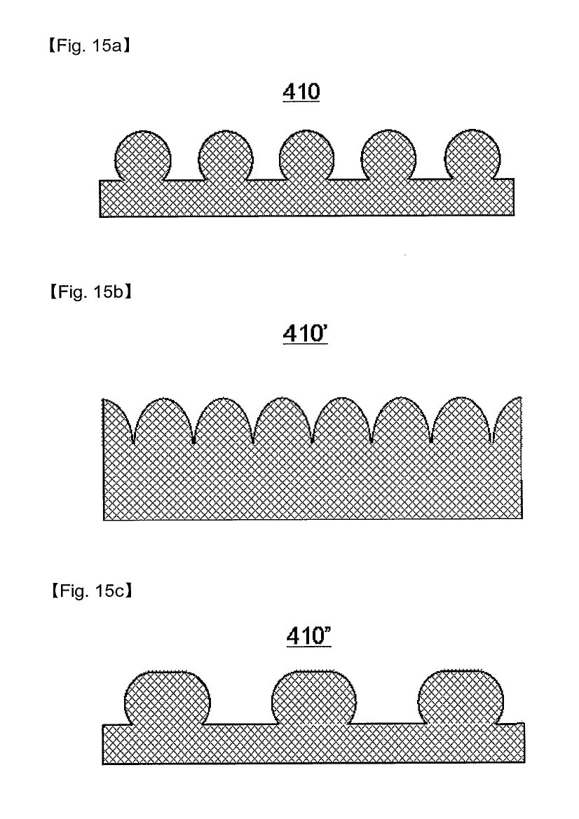

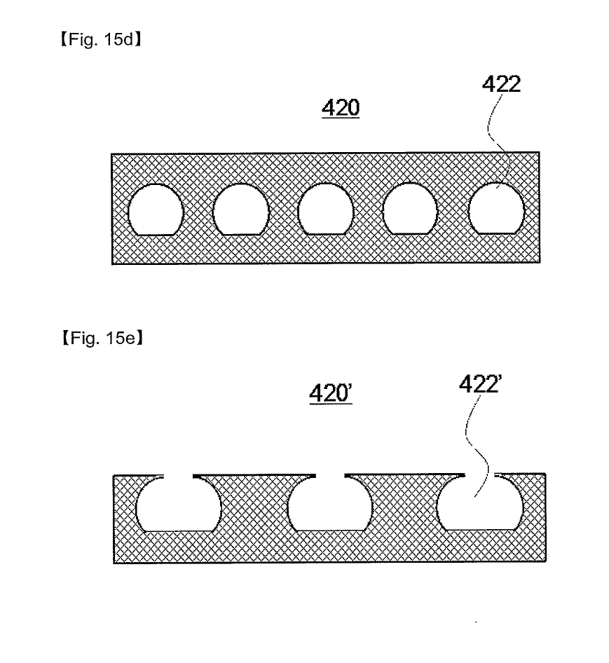

FIGS. 15a to 15e show various examples of plastic molds having a given shape according to the present invention. The plastic mold 410 shown in FIG. 15a is formed using the polymer patterns shown in FIG. 3b so that the vertical cross-section of at least one of protrusion patterns formed on the mold surface has a rounded surface. The plastic mold 410′ shown in FIG. 15b is formed using the polymer patterns shown in FIG. 7 so that protrusion patterns formed on the mold surface have a rounded surface at a very high density.

The plastic mold 410″ shown in FIG. 15c is so formed that at least one of protrusions formed on the mold surface has a larger area than that of the rounded surface shown in FIG. 15a. The plastic mold 420 shown in FIG. 15d is so formed that it has a plurality of the internal empty spaces 422 having a rounded cross-section. The plastic mold 420′ shown in FIG. 15e is so formed that the top of each of the internal empty spaces 422′ having a rounded cross-section is open to form concave patterns.

Such empty spaces 422 and 422′ can be used as microfluidic channels in various applications, including biotechnological researches as well as devices and apparatuses which use fluid flow channels.

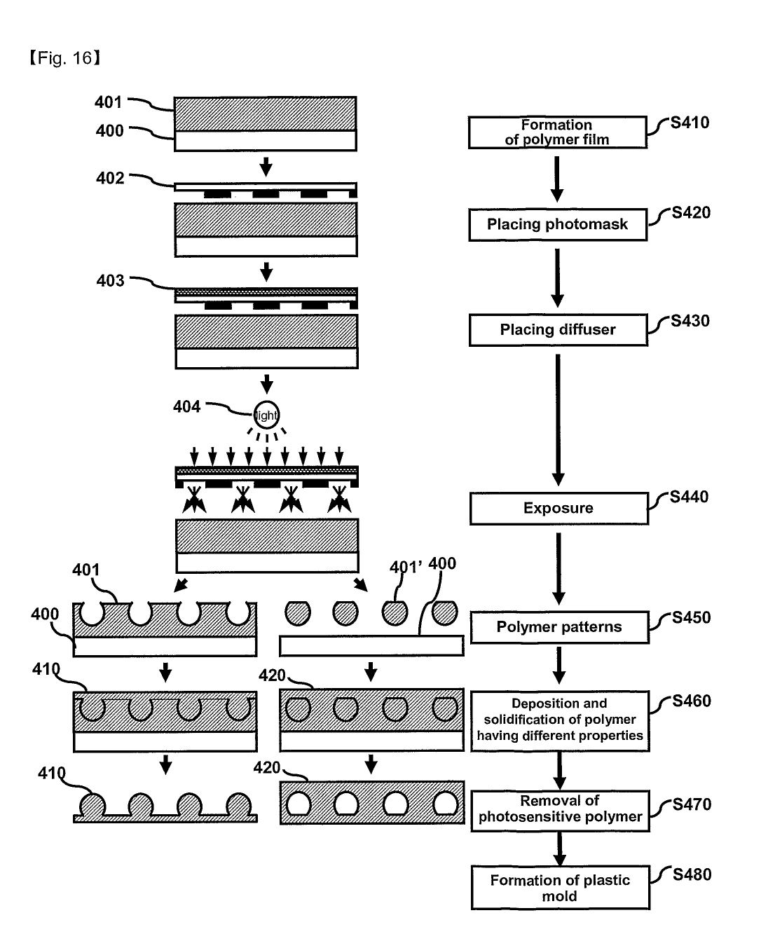

Methods of forming the inventive plastic molds having such structures are shown in FIG. 16.

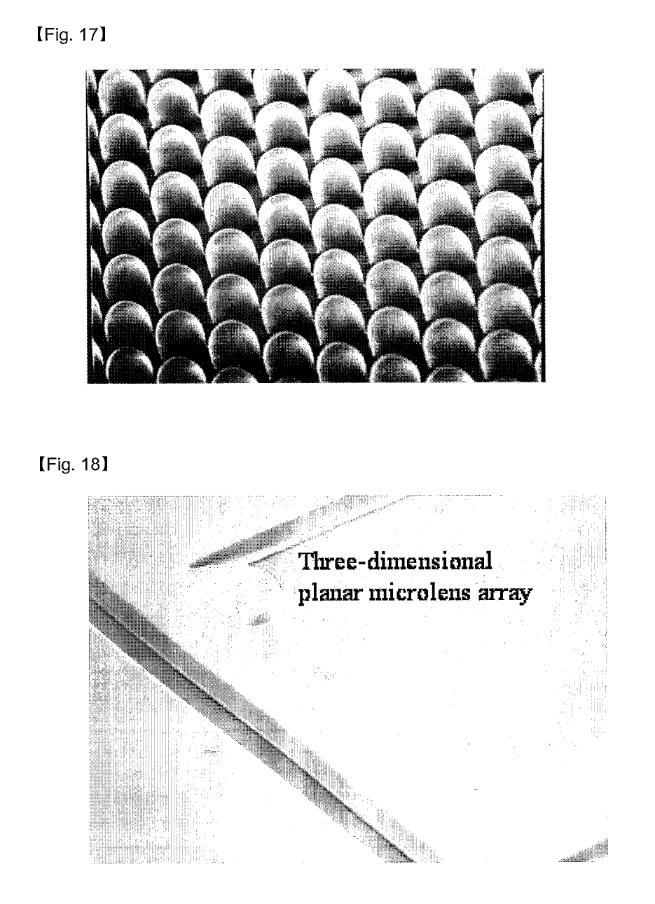

FIG. 16 is a process flow diagram showing the methods of forming the plastic molds according to the present invention, FIG. 17 is a secondary electron microscopic photograph taken for a portion of a plastic microlens array formed according to the methods shown in FIG. 16, and FIG. 18 is a secondary electron microscopic photograph taken for a portion of a planar microlens array formed according to the methods in FIG. 16.

Referring to FIG. 16, the method of forming the plastic molds according to the present invention broadly comprises the steps of forming the polymer patterns, and the steps of forming the plastic mold patterns by the resulting polymer patterns.

Namely, a photosensitive polymer is deposited on the substrate 400 to form the polymer film 401 on which the photomask having a given pattern formed thereon is placed. On the photomask 402, the diffuser 403 having high light-scattering ability is placed (S410-S430). Then, using the light source 404, the polymer film 401 is irradiated with light of a given wavelength. At this time, the perpendicularly incident light emitted from the light source 404 is irradiated on the polymer film 401 in random directions after passing through the diffuser 403, so as to form the first and second polymer patterns 401 and 401′ having a curved surface of a circular or oval shape, the top of which is cut in a straight line (S440 and S450). In this case, the first and second polymer patterns 401 and 401′ are different depending on the properties of the photosensitive polymers used.

On the first and second polymer patterns 401 and 401′ thus formed, the polymers 410 and 420 having different properties from the photosensitive polymers are deposited and solidified. The solidified polymer 410 is separated from the photosensitive polymer 401, thus forming plastic molds (S460 and S480). And the solidified polymer 420 is separated from the substrate 400, and the photosensitive polymer 401′ in the solidified polymer 420 is removed by a remover, thus forming plastic molds (S460-S480).

The plastic molds having rounded protrusions on the surface thereof, prepared by the above-described methods, can be used as microlens arrays as shown in FIG. 17. These microlens arrays have advantages in that they are prepared in a very simple and stable manner as compared to the prior microlens arrays, and they can be fabricated in various shapes so as to provide various optical properties.

Also, the plastic mold having a rounded cross-section only at a portion of the surface thereof can be used as a three-dimensional planar microlens array as shown in FIG. 18. This three-dimensional planar microlens array is advantageous in that it has better light collection efficiency than that of the prior two-dimensional microlens array, and thus, it can maximize the efficiencies of light detection systems of biochips, optical interconnections between optical fibers, and the like.

1. Polymer patterns formed on a substrate in a given shape, the polymer patterns having at least one pattern which is concave from the surface of the polymer patterns in a direction perpendicular to the substrate and extends in a direction parallel to the substrate, wherein the vertical cross-section of the concave pattern has at least one curved surface.

2. The polymer patterns of claim 1, wherein the vertical cross-section of the concave pattern has a circular or oval shape, the top of which is cut in a straight line.

3. The polymer patterns of claim 1, wherein the concave patterns are close to each other so as to have high density, as the distance between the adjacent polymer patterns is reduced.

4. The polymer patterns of claim 1, wherein the polymer is one of a positive photosensitive polymer and a negative photosensitive polymer.

5. The polymer patterns of claim 1, wherein the vertical cross-section of the concave pattern has a circular or oval shape whose top and bottom are cut in a straight line, and it satisfies the following relation:
90°>A>180°
wherein A represents the angle between the lower surface of the polymer patterns and a straight line which connects a point where the upper surface of the polymer patterns meets the concave pattern to a point where the lower surface of the polymer patterns meets the concave pattern.

6. A method for forming polymer patterns on a substrate in a given shape, the method comprising the steps of:
(a) applying a photosensitive polymer on the substrate to form a polymer film;
(b) placing a photomask on the polymer film; and
(c) irradiating the polymer film with a light moving in any directions through the photomask, so as to form at least one pattern which is concave from the surface of the polymer film in a direction perpendicular to the substrate and extends in a direction parallel to the substrate, wherein the vertical cross-section of the concave pattern has at least one curved surface.

7. The method of claim 6, wherein the step (b) further comprises the substep (b-1) of placing a diffuser on the photomask, in which the diffuser serves to change the light moving in any direction into a light source perpendicularly incident to the surface of the polymer film and to scatter the perpendicularly incident light source in any directions.

8. Metal film patterns formed on a substrate in a given shape, the metal film patterns having at least one pattern which is concave in a direction perpendicular to the substrate and extends in a direction parallel to the substrate, wherein the vertical cross-section of the concave pattern has at least one curved surface.

9. The metal film patterns of claim 8, wherein the inside of the metal film patterns is filled with polymer.

10. The metal film patterns of claim 9, wherein the inside of the metal film patterns is formed of empty space.

11. The metal film patterns of claim 9, wherein the top of the metal film patterns is open.

12. A method for forming metal film patterns on a substrate in a given shape, the method comprising the steps of:
(a) applying a photosensitive polymer on the substrate to form a polymer film;
(b) placing a photomask on the polymer film;
(c) irradiating the polymer film with a light moving in any direction through the photomask, so as to form at least one pattern which is concave in a direction perpendicular to the substrate and extends in a direction parallel to the substrate, wherein the vertical cross-section of the concave pattern has at least one curved surface; and
(d) applying a metal film on the polymer patterns.

13. The method of claim 12, wherein the step (b) further comprises the substep (b-1) of placing a diffuser on the photomask, in which the diffuser serves to change the light moving in any direction into a light source perpendicularly incident to the surface of the polymer film and to scatter the perpendicularly incident light source in any directions.

14. The method of claim 12, wherein the step (b) of applying the metal film is performed by thin film deposition methods, including sputtering, or thick film-forming methods, including plating.

15. The method of claim 12, which further comprises, after the step (d), the step of removing the polymer by a remover.

16. A metal film electrode having a curved metal electrode formed by the method of claim 12, in which the curved metal electrode is formed in such a manner that the curved metal electrode and an electrode opposite thereto are in an “on” or “off” state (closed or open state) depending on the voltage applied across the two electrodes.

17. Cantilever beams formed by the method of claim 12, which have a round cross-section.

18. Metal patterns formed on a substrate in a given shape, the metal patterns having at least one pattern which is concave in a direction perpendicular to the substrate and extends in a direction parallel to the substrate, wherein the vertical cross-section of the concave pattern has at least one curved surface.

19. The metal patterns of claim 18, wherein the vertical cross-section of the concave pattern has a circular or oval shape, the top of which is cut in a straight line.

20. A method for forming metal patterns on a substrate in a given shape, the method comprising the steps of:
(a) applying a photosensitive polymer on the substrate to form a polymer film;
(b) placing a photomask on the polymer film; and
(c) irradiating the polymer film with a light moving in any direction through the photomask, so as to form at least pattern which is concave in a direction perpendicular to the substrate and extends in a direction parallel to the substrate, wherein the vertical cross-section of the concave pattern has at least one curved surface;
(d) depositing a metal material on the polymer patterns; and
(e) removing the polymer by a remover.

21. The method of claim 20, wherein the step (b) further comprises the substep (b-1) of placing a diffuser on the photomask, in which the diffuser serves to change the light moving in any direction into a light source perpendicularly incident to the surface of the polymer film and to scatter the perpendicularly incident light in any directions.

22. The method of claim 20, wherein the step (b) of applying the metal film is performed by thin film deposition methods, including sputtering, or thick film-forming methods, including plating.

23. Metal interconnections formed by the method of claim 20, which have a round cross-section.

24. A plastic mold having a given shape, in which all or part of the vertical cross-section of at least one protrusion formed on the surface of the plastic mold has a round surface.

25. The plastic mold of claim 24, wherein the inside of the plastic mold has empty spaces.

26. The plastic mold of claim 25, wherein the empty spaces are used as microfluidic channels.

27. A method for forming a plastic mold having a given shape, the method comprising the steps of:
(a) applying a photosensitive polymer on the substrate to form a polymer film;
(b) placing a photomask on the polymer film;
(c) irradiating the polymer film with a light moving in any direction through the photomask, so as to form polymer patterns, all or part of the vertical cross-section of which has a round surface;
(d) applying and solidifying a polymer having different properties from the photosensitive polymer on the polymer patterns;
(e) separating the solidified polymer from the substrate; and
(f) removing the photosensitive polymer from the solidified polymer.

28. A microlens array formed using the round protrusions of the plastic mold formed by the method of claim 27.

29. A three-dimensional planar microlens array formed using the round protrusions of the plastic mold formed by the method of claim 27.
